(19) United States
(12) Patent Application Publication
(10) Pub. No.: US 2008/0237584 A1
(43) Pub. Date: Oct. 2, 2008

(54) Organic Component and Electric Circuit Comprising Said Component

(75) Inventors: Andreas Ullmann, Zirndorf (DE); Walter Fix, Nurnberg (DE)

Correspondence Address: CARELLA, BYRNE, BAIN, GILFILLAN, CECCHI,;STEWART & OLSTEIN, 5 BECKER FARM ROAD, ROSELAND, NJ, 07068, US

(73) Assignee: Polylc GmbH & Co. KG, Furth (DE)

(21) Appl. No.: 12/065,757

(22) PCT Filed: Sep. 5, 2006
(86) PCT No.: PCT/EP2006/008623

§ 371 Date: Apr. 2, 2008

(30) Foreign Application Priority Data
Sep. 6, 2005 (DE) 102005042166.0

(51) Int. Cl. H01L 51/00

(52) U.S. Cl. 257/40; 257/E51.001

(57) ABSTRACT

The invention relates to an organic component and an electric circuit containing at least one organic component of this type, comprising the following layers:
a first electrode layer composed of a first electrically conductive material,
a second electrode layer composed of a second electrically conductive material,
an organic semiconductor layer, and
at least one insulator layer composed of a dielectric material; wherein
a) the first electrode layer and the second electrode layer are arranged in the same plane alongside one another at a distance A,
b) the organic semiconductor layer at least partly covers the first electrode layer and the second electrode layer and furthermore spans the distance A, and wherein
c) a first insulator layer covers the organic semi-conductor layer on its side remote from the two electrode layers.

The invention relates to a novel organic component, referred to as actuator hereinafter, and to an electric circuit comprising at least one actuator of this type.

As already described in WO 03/081671, logic gates such as, for example, NAND, NOR or inverters are the elementary constituent parts of an integrated digital electronic circuit. In this case, the switching speed of the integrated circuit depends on the speed of the logic gates and not on the speed of the individual transistors. In conventional silicon semiconductor technology, these gates are realized by using both n- and p-conducting transistors and are very fast as a result. In the case of organic circuits, that is difficult to realize because there are no n-type semi-conductors that are good enough (e.g. with regard to the charge carrier mobility). For organic circuits that means that a traditional resistor is used instead of the n-conducting transistor. In this case, the term “traditional resistor” denotes a component having a linear current-voltage characteristic curve. What is disadvantageous about such logic gates having organic field effect transistors is that either they switch over slowly (if the charge-reversal currents, that is to say the integrals under the current-voltage curve, are very different) or they cannot be switched off (if the voltage swing in the current-voltage diagram is too small).

In order to form traditional resistors in the megohms range, very thin and long conductor tracks composed of electrically conductive material (metallic or organic conductors) are produced. Resistors formed in this way have to be formed separately and do not conform to a p-FET in a logic gate if the layer thickness of the semiconductor in the p-FET fluctuates due to production, such that it is not possible to form a circuit having reproducible properties or a functioning circuit at all.

In accordance with WO 03/081671, improved logic gates having organic field effect transistors have already been provided in which the missing “traditional” n-conducting transistors were replaced by an organic p-conducting field effect transistor (p-OFET) rather than by traditional resistors.

By using a p-OFET instead of an n-conducting transistor, however, an additional parasitic capacitance—the transistor capacitance—is incorporated into the logic gate and adversely influences the circuit properties.

It is an object of the invention, then, to find an alternative load component for a fast logic gate which can be operated with a low supply voltage and correspondingly conforms in the case of fluctuations in the thickness of a semiconductor layer in a p-FET. It is furthermore an object of the invention to demonstrate suitable electric circuits for such a logic gate.

The object is achieved for the load component by means of an organic component, referred to as actuator hereinafter, comprising the following layers:
a first electrode layer composed of a first electrically conductive material,
a second electrode layer composed of a second electrically conductive material,
an organic semiconductor layer, and
at least one insulator layer composed of a dielectric material; wherein
a) the first electrode layer and the second electrode layer are arranged in the same plane alongside one another at a distance A,
b) the organic semiconductor layer at least partly covers the first electrode layer and the second electrode layer and furthermore spans the distance A, and wherein
c) a first insulator layer covers the organic semi-conductor layer on its side remote from the two electrode layers.

It has been found that it is only with such a construction that a stable current-voltage characteristic is ensured for the organic component according to the invention. This is because if the first insulator layer is omitted, a usable component does not arise. The causes of the stabilizing behavior of the first insulator layer have not yet been fully clarified.

Since the electrode layers of the actuator are situated in the same plane alongside one another and can moreover be made very thin, the actuator has approximately no capacitance. The current flow can be set optimally by way of the geometry of the electrode layers and the formation of the organic semiconductor layer.

The actuator according to the invention provides an alternative load component for a fast logic gate which can be operated with a low supply voltage within the range of −1 volt to −100 volts.

Owing to the layer sequence of its individual layers and the layer materials required, the actuator can be formed very simply together with the layers of a p-FET. It is thus appropriate to form the source and drain electrodes of the p-FET and the first and the second electrode layer of the actuators in one work operation on one substrate in the same plane and from the same material and furthermore to form the semiconductor layer of the p-FET and the semiconductor layer of the actuator in one work operation on the electrode layers in the same plane and from the same material. This ensures that the thickness of the semiconductor layer of the actuator and that of the p-FET are formed with the same thickness and the actuator therefore conforms directly to the p-FET in terms of its electrical properties.

It has proved to be worthwhile if the actuator has a second insulator layer, which covers the organic semiconductor layer in the region of the distance A between the first and the second electrode layer. This protects the organic semiconductor layer against possible ambient influences also on the side opposite to the first insulator layer.

Preferably, the second insulator layer furthermore covers those sides of the two electrode layers which are remote from the organic semiconductor layer. Thus, said electrode layers are also protected against ambient influences.

Furthermore, it has proved to be expedient if the second insulator layer functions as a mechanical carrier, in particular as a flexible mechanical carrier. In this case, the carrier can also be formed in multilayered fashion and comprise, depending on the desired properties, paper, plastic, metal, fabric layers or inorganic layers, wherein the layer element of the carrier which adjoins the electrode layers and the semiconductor layer must however in principle be formed in electrically insulating fashion as second insulator layer. Preferably, the carrier is provided by a film composed of PET, PVP, polyamide, PP, PEN, polyimide, glass, glass-coated plastic, polycarbonate, or composed of paper—if appropriate coated with plastic.

Ideally, the distance A between the first electrode layer and the second electrode layer is chosen within the range of 1 μm to 100 μm.

It has proved to be worthwhile if the electrode layers in each case have a layer thickness within the range of 1 nm to 10 μm, in particular of 1 nm to 100 nm.

It is preferred to form the first and the second electrically conductive material for forming the electrode layers from metal, a metal alloy, a conductive polymer, a conductive adhesive, a conductive substance with conductive inorganic particles in a polymer matrix or from a paste/ink containing electrically conductive particles.

In this case, the electrode layers can be formed in multilayered fashion, in particular be formed from a plurality of metal layers and/or a plurality of polymer layers and/or a plurality of paste/ink layers.

The organic semiconductor layer preferably has a layer thickness within the range of 1 nm to 10 μm, in particular within the range of 1 nm to 10 nm.

The first insulator layer preferably has a layer thickness within the range of 1 nm to 10 μm, in particular within the range of 200 nm to 800 nm.

It has proved to be expedient if the second insulator layer has a layer thickness of at least 1 μm, preferably of approximately 50 μm.

It is preferred to form the organic semiconductor layer from polythiophene, polyterthrophene, polyfluorene, pentacene, tetracene, oligothrophene, inorganic silicon embedded in a polymer matrix, nanosilicon or polyarylamine.

Furthermore, it has proved to be advantageous to form the first insulator layer as an organic polymer layer, in particular to form it from polymethyl methacrylate (PMMA), PVP, PHS, PS, polystyrene copolymers, urea resins or PMMA copolymers.

With regard to cost-effective production of the actuator it is preferred if at least the organic semi-conductor layer is formed by means of a liquid, in particular by a printing method. In this case, preference is given in particular to continuous printing methods in which a film substrate is conveyed from roll to roll and printed with the functional layers of the actuator and, if appropriate, further components for forming an electric circuit. However, not only traditional printing methods are suitable here but also spraying, coating, blade coating or some other application method that can be conducted as a continuous process.

The object is furthermore achieved for the electric circuit by virtue of the fact that the latter comprises at least one actuator as described above, wherein the electronic circuit forms a logic gate.

In this case, it has proved to be worthwhile if the logic gate has at least one driver component and at least one load component, wherein the at least one driver component is provided by a transistor and the at least one load component is provided by the actuator. Furthermore, it has proved to be advantageous here if an organic field effect transistor (OFET), which is preferably a p-conducting OFET, is used as the transistor.

Thus, during the production of the electric circuit, preferably by means of a printing process, the semi-conductor layer of the transistor can be formed simultaneously and in one work operation with the organic semiconductor layer of the actuator. If layer thickness fluctuations occur in the organic semi-conductor layer due to production, then this alters not only the properties of the transistor but also the values of the actuator to the same extent, whereby the function of the logic gate is preserved.

As already explained further above, on account of the similar layer construction and the similar layer sequences for actuator and in particular p-OFET, joint production of individual layers of these components in a single work operation is readily and unproblematically feasible, identical layer materials being used. In this case, the organic semiconductor layer is formed with such a large area that both the actuator and the p-OFET partake of it.

The logic gate preferably forms an inverter, a logic NOR, a logic NAND or ring oscillator—one composed of inverters.

It has proved to be worthwhile if the inverter has at least one p-conducting OFET and at least one actuator.

It has furthermore proved to be worthwhile if the logic NOR has two parallel-connected p-conducting OFETs and one actuator.

The logic NAND preferably has two series-connected p-conducting OFETs and one actuator.

Preferably, the ring oscillator has an odd number n of above inverters, wherein an output of a first inverter I₁ is connected to an input of a further inverter I₂, and wherein a last inverter Iₙ is connected to the first inverter I₁ for forming the ring.

The use of an actuator according to the invention as a load component in an electric circuit, in particular for forming a logic gate, is ideal.

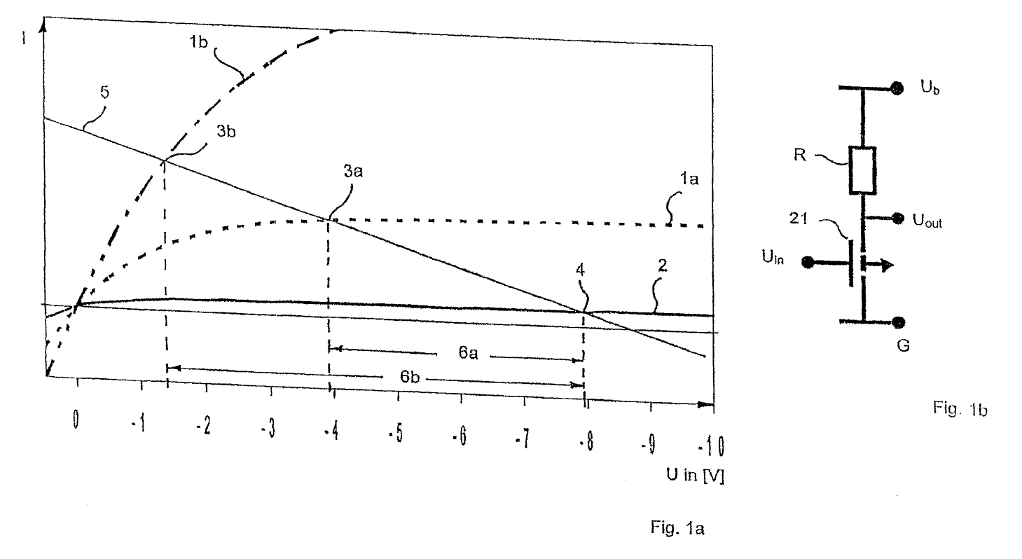

The invention is explained in more detail below with reference to FIGS. 1a to 6. Thus,

FIG. 1a shows a current-voltage diagram of a first inverter having a traditional resistor and an OFET according to the prior art,

FIG. 1b shows a circuit diagram of the first inverter that is associated with FIG. 1a,

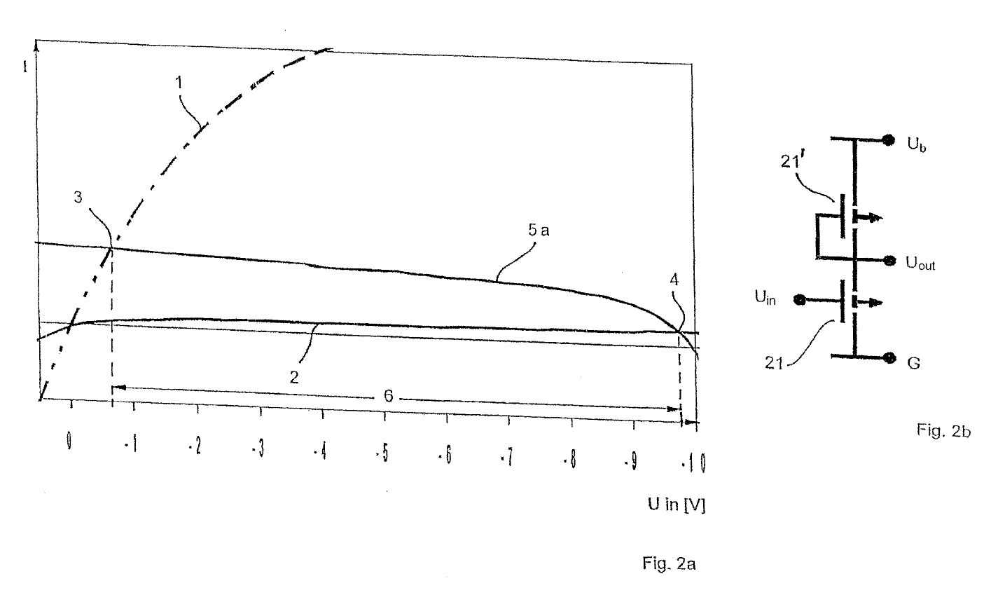

FIG. 2a shows a current-voltage diagram of a second inverter having two OFETs according to the prior art,

FIG. 2b shows a circuit diagram of the second inverter that is associated with FIG. 2a,

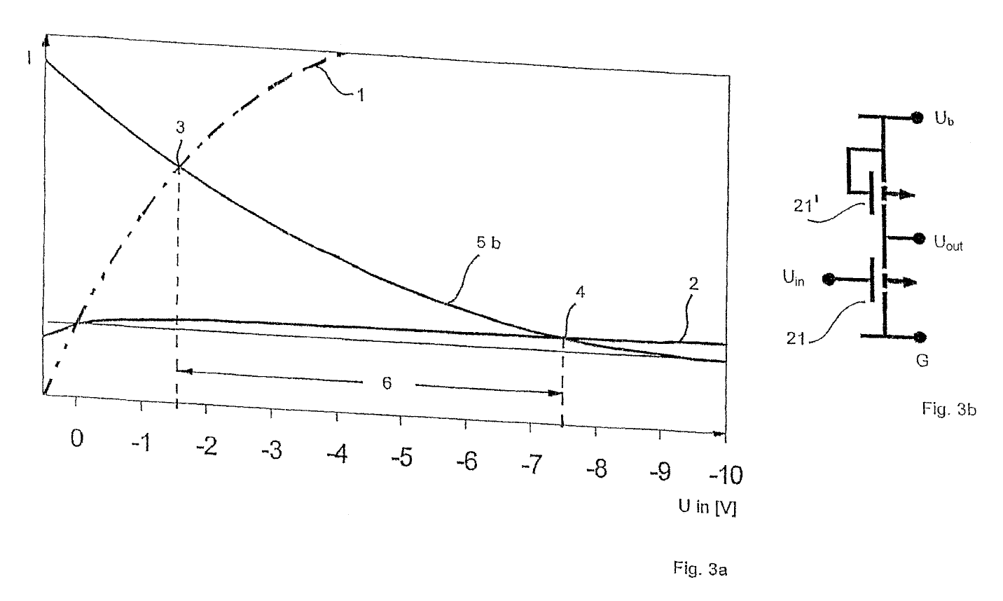

FIG. 3a shows a current-voltage diagram of a third inverter having two OFETs according to the prior art,

FIG. 3b shows a circuit diagram of the third inverter that is associated with FIG. 3a,

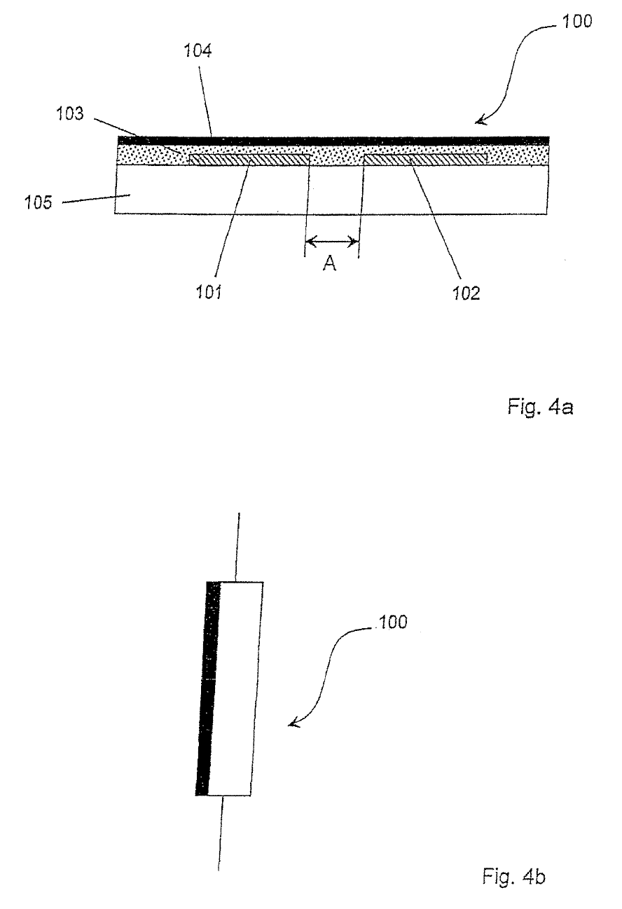

FIG. 4a shows the construction of an actuator according to the invention in cross section,

FIG. 4b shows a circuit symbol assigned to the actuator,

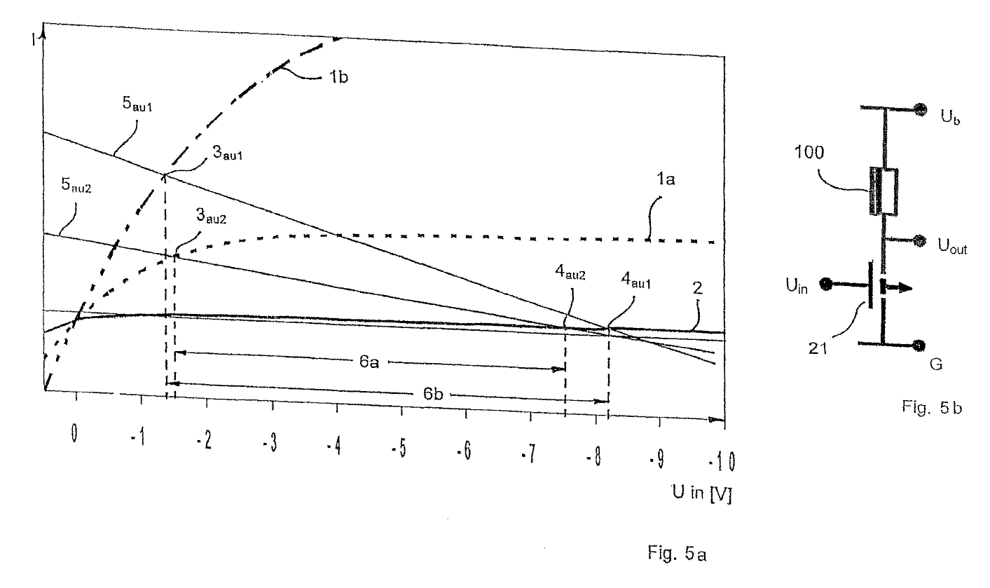

FIG. 5a shows a current-voltage diagram of an inverter according to the invention,

FIG. 5b shows a circuit diagram of an inverter according to the invention that is associated with FIG. 5a, and

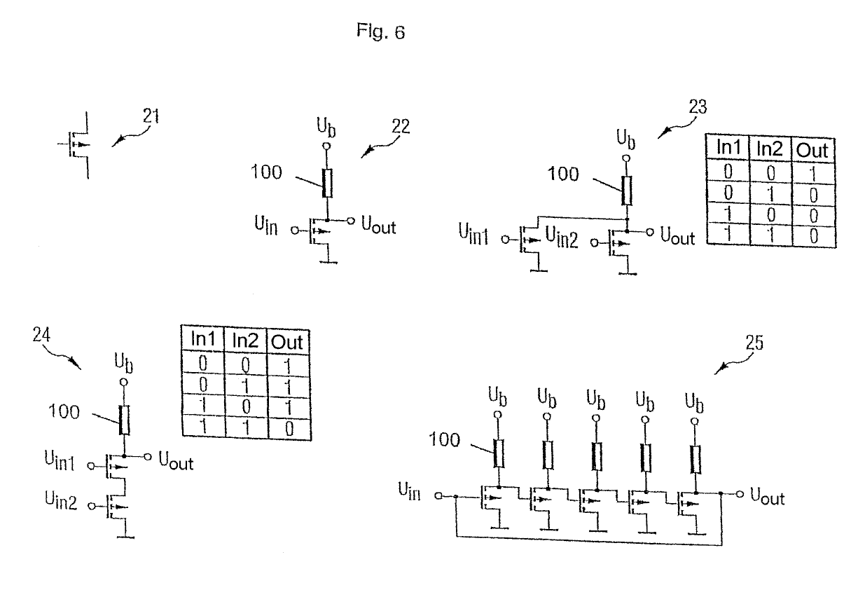

FIG. 6 shows exemplary embodiments of logic gates with actuators.

When using the traditional resistor (cf. FIGS. 1a and 1b with regard to the prior art), the logic gates either switch over too slowly or cannot be switched off.

In FIG. 1a, the on characteristic curve 1b and the off characteristic curve 2 of an inverter having a p-OFET 21 and a traditional resistor R in accordance with FIG. 1b are depicted in a current-voltage diagram. The interconnection of the inverter can be seen from FIG. 1b, where the supply voltage U_{b}, the ground G, the p-OFET 21 (also see FIG. 6), the input voltage Uᵢₙ and the output voltage Uₒᵤₜ and also the resistor R can be discerned. In this case, the gate electrode of the p-OFET 21 is at Uᵢₙ. The characteristic curves 1b and 2 in accordance with FIG. 1a correspond to the switched-on and the switched-off state. The points of intersection 3b and 4 of the curves 1b and 2 with the resistance line 5 of the traditional resistor R correspond to the switching points of the inverter. The output voltage swing 6b of the inverter is very large, which means that the inverter can be switched on and off well. The charge-reversal currents correspond to area integrals between, on the one hand, the curves 1b and 5 under the curve 1b in the region 6b and, on the other hand, between the curves 5 and 2 under the curve 5 in the region 6b.

FIG. 1a furthermore shows the on characteristic curve la and the off characteristic curve 2 of an inverter in accordance with FIG. 1b which is operated with a p-OFET 21 whose layer thickness of the organic semi-conductor, due to production, is made slightly thinner than in a p-OFET 21 in accordance with the on characteristic curve 1b. Said characteristic curves la and 2 correspond to the switched-on and the switched-off state of the inverter. The points of intersection 3a and 4 of the curves 1a and 2 with the resistance line 5 of the traditional resistor R correspond to the switching points of the inverter. The output voltage swing 6a of the inverter is significantly smaller, which means that the inverter can be switched on and off more poorly. The charge-reversal currents correspond to the area integrals between, on the one hand, the curves 1a and 5 under the curve 1a in the region 6a and, on the other hand, between the curves 5 and 2 under the curve 5 in the region 6a and, in terms of their order of magnitude, are equal in magnitude, but the voltage swing 6a is only small. Thus, the inverter in accordance with the characteristic curve 1a with a slightly thinner semiconductor layer of the p-OFET 21 cannot be entirely switched off. In the worst case, the asymmetrical charging/discharging on account of the fluctuations in the thickness of the semi-conductor layer of the p-OFET 21 can have the effect that the logic capability of the circuit in accordance with FIG. 1b is entirely lost.

The current-voltage diagram of a logic gate from the prior art which comprises two p-conducting OFETs is shown in FIG. 2a. The interconnection of the inverter can be seen from FIG. 2b, where the supply voltage U_{b}, the ground G, two p-FETs 21, 21′ (also see FIG. 6), the input voltage Uᵢₙ and the output voltage Uₒᵤₜ can be discerned. In this case, the gate electrode of the p-FET 21 is at Uᵢₙ. The characteristic curves 1 and 2 in accordance with FIG. 2a correspond to the switched-on and the switched-off state. The points of intersection 3 and 4 of the curves 1 and 2 with the resistance line 5a of the p-FET 21′ correspond to the switching points of the inverter. The output voltage swing 6 of the inverter is very large, which means that the inverter can be switched on and off well. The charge-reversal currents (area integrals between, on the one hand, the curves 1 and 5a under the curve 1 in the region 6 and, on the other hand, between the curves 5a and 2 under the curve 5a in the region 6 correspond to the charge-reversal currents) are very different, such that the inverter can only switch slowly on account of its large capacitance. A discrete supply voltage is required for the inverter since otherwise the ratio of the geometry factors of the p-FETs with respect to one another is not optimal. The geometry factor is understood to be the ratio of channel width W to channel length L (channel is formed by semiconductor layer) of a transistor. Since the p-FET 21′ is at Uₒᵤₜ and is therefore always switched off, only little charging current is available for it. Assuming a geometry factor for the p-FET 21 of 1 and thus a capacitance for the p-FET 21 of 1 and a geometry factor for the p-FET 21′ of 5 and thus a capacitance for the p-FET 21′ of 5, this results in a 6-fold total capacitance for the inverter. High charging currents and short charging times thus result.

A further current-voltage diagram of a logic gate from the prior art which comprises two p-conducting OFETs is shown in FIG. 3a. The interconnection of the inverter can be seen from FIG. 3b, where the supply voltage U_{b}, the ground G, two p-OFETs 21, 21′ (also see FIG. 6), the input voltage Uᵢₙ and the output voltage Uₒᵤₜ can be discerned. In this case, the gate electrode of the p-OFET 21′ is at U_{b}. The characteristic curves 1 and 2 in accordance with FIG. 3a correspond to the switched-on and the switched-off state. The points of intersection 3 and 4 of the curves 1 and 2 with the resistance line 5b of the p-OFET 21′ correspond to the switching points of the inverter. The output voltage swing 6 of the inverter is relatively small, which means that the inverter can be switched on and off poorly. The charge-reversal currents (area integrals between, on the one hand, the curves 1 and 5b under the curve 1 in the region 6 and, on the other hand, between the curves 5b and 2 under the curve 5b in the region 6 correspond to the charge-reversal currents) are very similar, such that the inverter can switch relatively rapidly on account of its large currents and no capacitance. However, a high supply voltage is required for the inverter since the gain factor goes only slightly above 1. On account of the high supply voltage U_{b}, the logic is in turn less stable. The p-OFETs degrade starting from a voltage of approximately 20 V or more.

FIG. 4a then shows the basic construction of an actuator 100 in cross section. The first electrode layer 101 and the second electrode layer 102 are shown, which are arranged on a flexible carrier 105 composed of PET. In this case, the flexible carrier 105 forms the second insulation layer. The first and the second electrode layer 101, 102 are formed from gold that is sputtered onto the carrier 105 in a thickness of approximately 40 to 50 nm. The first electrode layer 101 and the second electrode layer 102 are arranged alongside one another in the same plane on the carrier 105, said electrode layers being arranged apart at a distance A from one another. The distance A is in this case approximately 10 μm. An organic semiconductor layer 103 composed of polythiophene covers the first and the second electrode layer 101, 102 and also spans the distance A. A first insulator layer 104 composed of PMMA covers the organic semiconductor layer 103 on its side remote from the two electrode layers 101, 102. FIG. 4b shows a new circuit symbol assigned to the actuator 100, said symbol being used below in the illustration of logic gates (see FIGS. 5b and 6).

FIG. 5a shows a current-voltage diagram of an inverter which is formed according to the invention and which comprises a p-conducting OFET 21 and an actuator 100. In FIG. 5a, the on characteristic curve 1b and the off characteristic curve 2 of an inverter in accordance with FIG. 5b are depicted in the current-voltage diagram. The interconnection of the inverter can be seen from FIG. 5b, where the supply voltage U_{b}, the ground G, a p-OFET 21, the input voltage Uᵢₙ and the output voltage Uₒᵤₜ and also the actuator 100 can be discerned. In this case, the gate electrode of the p-FET 21 is at Uᵢₙ. The characteristic curves 1b and 2 in accordance with FIG. 5a correspond to the switched-on and the switched-off state. The points of intersection 3ₐᵤ₁ and 4ₐᵤ₁ of the curves 1b and 2 with the resistance line 5ₐᵤ₁ of the actuator 100 correspond to the switching points of the inverter. The output voltage swing 6b of the inverter is large, which means that the inverter can be switched on and of f well. The charge-reversal currents (area integrals between, on the one hand, the curves 1b and 5ₐᵤ₁ under the curve 1b in the region 6b and, on the other hand, between the curves 5ₐᵤ₁ and 2 under the curve 5ₐᵤ₁ in the region 6b correspond to the charge-reversal currents) are different, which means that the inverter can switch more rapidly to “high”, but more slowly to “low”.

In this case, the semiconductor layer of the actuator 100 was formed using printing technology and simultaneously with the semiconductor layer of the p-OFET 21, such that an identical layer thickness of the semiconductor layer was produced in both components.

FIG. 5a furthermore shows the on characteristic curve 1a and the off characteristic curve 2 of an inverter in accordance with FIG. 5b which is operated with a p-OFET 21 whose layer thickness of the semiconductor, due to production, is made slightly thinner than in a p-OFET 21 in accordance with the on characteristic curve 1b. In this case, the semiconductor layer of the actuator 100 was formed using printing technology and simultaneously with the semiconductor layer of the p-OFET 21, such that in this case, too, an identical layer thickness of the semiconductor layer was produced in both components.

The characteristic curves 1a and 2 correspond to the switched-on and the switched-off state of the inverter. It can clearly be discerned from this illustration that the actuator concomitantly scales its electrical properties if fluctuations in the layer thickness of the semiconductor layer formed using printing technology occur. The points of intersection 3ₐᵤ₂ and 4ₐᵤ₂ of the curves 1a and 2 with the resistance line 5ₐᵤ₂ of the actuator 100 correspond to the switching points of the inverter and are shifted only slightly with respect to the points of intersection 3ₐᵤ₁ and 4ₐᵤ₁. Consequently, the output voltage swing 6a of the inverter is only slightly smaller than the voltage swing 6b, which means that the actuator 100 is able to match the electrical properties of inverters having fluctuations in the layer thickness of the semiconductor layer to one another. The charge-reversal currents (area integrals between, on the one hand, the curves 1a and 5ₐᵤ₂ under the curve 1a in the region 6a and, on the other hand, between the curves 5ₐᵤ₂ and 2 under the curve 5ₐᵤ₂ in the region 6a correspond to the charge-reversal currents) are almost unchanged in terms of their magnitude ratio with respect to one another, such that no significant changes occur in the switching behavior of the inverter either.

FIG. 6 shows some exemplary embodiments of logic gates comprising actuators:

Inverter 22, NOR 23, NAND 24, ring oscillator 25. In this case, the circuit symbol 21 symbolizes the p-conducting OFET.

The inverter 22 can be formed by an interconnection of an OFET together with an actuator. In this case, a signal applied to the input (“high” or “low”) is changed over (inverted) and is then present at the output (as “low” or “high”). In order to obtain a logic NOR, two transistors can be connected in parallel. The states are forwarded to the output by the application of an input voltage in accordance with the table (“low”=“0”; “high”=“1”). A NAND functions analogously, and can be realized by series-connected transistors.

One embodiment—not shown—of the logic gate is a flip-flop, for example, which can likewise be constructed from OFETs and actuators.

It should be added that the person skilled in the art can use the actuator in innumerable further electric circuits without having to take an inventive step.

1. An organic actuator component for a logic gate, comprising:
a first electrode layer comprising a first electrically conductive material;
a second electrode layer comprising a second electrically conductive material;
an organic semiconductor layer on at least the first and second electrodes; and
at least one insulator layer composed of a dielectric material; wherein
(a) the first electrode layer and the second electrode layer are coplanar alongside one another at a spaced apart distance A, wherein the distance A is within the range of 1 μm to 100 μ;
(b) the organic semiconductor layer at least partly covers the first electrode layer and at least partly covers the second electrode layer in a continuous layer spanning the distance A; and wherein
(c) a first insulator layer covers the organic semiconductor layer on its side remote from the two electrode layers.

2. The organic component as claimed in claim 1 including a second insulator layer wherein the organic semiconductor layer covers and is contiguous with the second insulator layer in the region of the distance A between the first and the second electrode layers.

3. The organic component as claimed in claim 2 wherein the second insulator layer covers that side of the two electrode layers which is remote from the organic semiconductor layer.

4. The organic component as claimed in claim 3 wherein the second insulator layer forms a flexible mechanical carrier.

5. The organic component as claimed in claim 1 wherein the electrode layers each have a layer thickness in the range of 1 nm to 1 μm.

6. The organic component as claimed in claim 1 wherein the first and the second electrodes are formed from at least one of metal, a metal alloy, a conductive polymer, a conductive adhesive, a conductive substance with conductive inorganic particles in a polymer matrix or from a paste/ink containing electrically conductive particles.

7. The organic component as claimed in claim 1 wherein the electrode layers each comprise multilayers.

8. The organic component as claimed in claim 1 wherein the electrode layers comprise at least one of a plurality of metal layers, a plurality of polymer layers or a plurality of paste/ink layers.

9. The organic component as claimed in claim 1 wherein the organic semiconductor layer has a layer thickness within the range of 1 nm to 10 μm.

10. The organic component as claimed in claim 1 wherein the organic semiconductor layer has a layer thickness within the range of 1 nm to 200 nm.

11. The organic component as claimed in claim 1 wherein the first insulator layer has a layer thickness within the range of 1 nm to 10 μm.

12. The organic component as claimed in claim 2 wherein the second insulator layer has a layer thickness of at least 1 μm.

13. The organic component as claimed in claim 1 wherein the organic semiconductor layer is formed from polythiophene, polyterthrophene, polyfluorene, pentacene, tetracene, oligothrophene, inorganic silicon embedded in a polymer matrix, nanosilicon or polyarylamine.

14. The organic component as claimed in claim 1 wherein the first insulator layer is an organic polymer.

15. The organic component as claimed in claim 14 wherein the organic polymer layer is formed from polymethyl methacrylate (PMMA), PVP, PHS, PS, polystyrene copolymers, urea resins or PMMA copolymers.

16. A method for producing the organic component as claimed in claim 1 comprising forming the at least the organic semiconductor layer from a liquid.

17. The method as claimed in claim 16 including printing at least the organic semiconductor layer from the liquid.

18. The organic component of claim 1 further including a logic gate electric circuit coupled to said electrodes.

19. The organic component as claimed in claim 18 wherein the logic gate electric circuit includes at least one driver component and at least one load component, wherein the at least one driver component is provided by a transistor and the at least one load component is provided by the organic component of claim 1.

20. The organic component as claimed in claim 19 wherein the transistor includes a semiconductor layer.

21. The organic component as claimed in claim 19 wherein the transistor comprises an organic field effect transistor (OFET) including a semiconductor layer.

22. The organic component as claimed in claim 18 wherein the logic gate comprises one of an inverter, a logic NOR, a logic NAND or a ring oscillator.

23. The organic component as claimed in claim 22 wherein the logic gate comprises the inverter and comprises at least one p-conducting OFET and at least one organic component as claimed in claim 1.

24. The organic component as claimed in claim 22 wherein the logic circuit comprises the logic NOR and includes two parallel-connected p-conducting OFETs and one organic component as claimed in claim 1.

25. The organic component as claimed in claim 22 wherein the logic circuit comprises the logic NAND which comprises two series-connected p-conducting OFETs and one organic component as claimed in claim 1.

26. The organic component as claimed in claim 22 wherein the logic circuit comprises the ring oscillator, which oscillator comprises an odd number n of said inverter wherein an output of a first inverter I₁ is connected to an input of a further inverter I₂, and wherein a last inverter Iₙ is connected to the first inverter I₁ for forming the ring oscillator.

27. A method for producing the organic component as claimed in claim 20 wherein the organic semiconductor layer of the organic component is formed simultaneously and in one work operation with the semiconductor layer of the transistor.

28. The organic component of claim 1 further including a logic circuit, the organic component of claim 1 being connected in circuit with the logic circuit and forming load component for the logic circuit.
